(19) United States
(12) Patent Application Publication
(10) Pub. No.: US 2011/0051389 A1
(43) Pub. Date: Mar. 3, 2011

(54) BOARD TERMINAL

(75) Inventor: Hideki GOTO, Yokkaichi-city (JP)

(73) Assignee: SUMITOMO WIRING SYSTEMS, LTD., Mie (JP)

(21) Appl. No.: 12/843,346

(22) Filed: Jul. 26, 2010

(30) Foreign Application Priority Data
Sep. 3, 2009 (JP) 2009-203866
Apr. 1, 2010 (JP) 2010-085374

(51) Int. Cl. H01R 12/30; H01B 5/00; H05K 1/14; H05K 1/11

(52) U.S. Cl. 361/803; 174/126.1; 174/267; 439/83

(57) ABSTRACT

A board terminal includes a metal wire and concave portions formed on peripheral surfaces along the length of the wire. The metal wire is cut to a predetermined length, and the concave portions are formed by pressing the peripheral surfaces of the wire at intermediate portions along the length thereof.

### CROSS-REFERENCE TO RELATED APPLICATIONS

The present application claims priority under 35 U.S.C. §119 of Japanese Applications No. 2009-203866, filed on Sep. 3, 2009, and No. 2010-085374, filed on Apr. 1, 2010, which are herein expressly incorporated by reference in their entirety.

### BACKGROUND OF THE INVENTION

1. Field of the Invention

The present invention relates to a board terminal soldered to a printed board.

2. Description of Related Art

A printed board is conventionally used for wiring a low power circuit, forming an electric circuit, and the like. A board terminal is provided to the printed board, in order to conduct a circuit on the board and an external circuit. The board terminal is generally fitted in and supported by a terminal base or a connector housing provided on the printed board. The terminal is inserted through a through-hole provided to the printed board and soldered thereto. The terminal is thereby conducted to the circuit on the board.

A pressed metal flat plate material is conventionally used as the board terminal. Due to a difference in coefficient of thermal expansion of the printed board and the terminal base and the like, however, solder cracks occur when an external force is exerted on a soldered portion. In order to address the problem, structures have been proposed, such as those disclosed in Japanese Utility Model Laid-open Publication No. H7-30460 and Japanese Patent Laid-open Publication No. 2001-327038. In the proposed structures, a step-shaped bent portion, or cranked structure, or the like, is provided to an intermediate portion of the board terminal, and the bent portion may be elastically deformed, thereby reducing an external force exerted on the soldered portion and preventing solder cracks.

When the bent portion is provided, however, the board terminal projects laterally at the bent portion, which interferes when the board terminal is held for soldering and the like, thus reducing workability. In addition, the bent portion having a large lateral projection amount is provided to the intermediate portion in a longitudinal direction. Thus, the efficiency of storing the board terminal deteriorates, and the efficiency of transporting the board terminal also tends to be reduced, as compared to the storage and transportation of flat board terminals.

### SUMMARY OF THE INVENTION

In view of the above, the present invention provides a board terminal having a new structure, the terminal allowing easy handling and preventing solder cracks from occurring in a state in which the terminal is mounted to a printed board.

A first aspect of the present invention provides a board terminal formed of a cut off wire obtained by cutting a metal wire at a predetermined length, wherein concave pressed portions are provided to external peripheral surfaces in a longitudinally intermediate portion of the cut off wire.

According to the present invention, the board terminal is formed of the cut off wire. Thus, pressing the longitudinally intermediate portion of the cut off wire forms the concave portions, while practicably preventing a projection from being formed on a reverse side of a pressed surface in pressing of an intermediate portion of a flat plate material. The longitudinally intermediate portion in the present aspect may be provided at any location between both end portions of the cut off wire, and the portion is not limited to a middle portion in the longitudinal direction.

Since the concave pressed portions are elastically deformed, a stress to a soldered portion can be released and reduced, and thus a solder crack can be prevented from occurring. Specifically, a curved portion is provided along a central axis line of the board terminal by forming the pressed portions, without forming a projection to a side of the board terminal, the central axis line being held as a line connecting the cross-sectional center. Rigidity is thus reduced, and thereby a portion easily elastically deformed relative to an external force can be provided.

In addition, projection to the side of the board terminal can be prevented, thus enhancing workability in soldering, and increasing the storage efficiency and improving the transportation efficiency. Further, it is unnecessary to change holding tools or manufacturing facility conventionally used for linear board terminals.

A second aspect of the present invention provides the board terminal according to the first aspect, wherein the concave pressed portions are provided to both side surfaces sandwiching a central axis of the cut off wire and at locations mutually offset in the axial direction.

According to the present aspect, the central axis line connecting the cross-sectional center can be set to have a wave shape having a larger curve in both directions as a whole. Thus, the stress to the soldered portion can be released in a more plurality of directions.

A third aspect of the present invention provides the board terminal according to the first or second aspect, wherein an opening size of the concave pressed portions is widened from a first side toward a second side in a circumferential direction of the cut off wire.

Thereby, the rigidity of the board terminal can be different in the circumferential direction in the pressed portions. A more effective diffusion effect can thus be obtained for a stress in a twisted direction around the central axis line.

A fourth aspect of the present invention provides the board terminal according to the third aspect, wherein the concave pressed portions are provided to both side surfaces sandwiching a central axis of the cut off wire and at locations mutually off in the axial direction; and the opening size of the concave pressed portions is widened from the first side toward the second side of the same circumferential direction of the cut off wire.

According to the present aspect, the pair of concave pressed portions are provided having the openings on the pair of side surfaces opposing in a perpendicular direction to the axis of the board terminal. Then, the opening size of the pair of concave pressed portions is gradually widened in a mutually reverse direction in the circumferential direction of the board terminal, in a projection in the perpendicular direction to the axis of the board terminal. In the projection in the perpendicular direction to the axis of the board terminal, the first concave portion is thus provided open to the right, and the second concave portion is provided open to the left. Thereby, a more effective diffusion effect can be achieved for the stress in the twisted direction.

A fifth aspect of the present invention provides the board terminal according to the first aspect, wherein longitudinal both end portions of the cut off wire are inserted through through-holes of two printed boards and soldered thereto; the concave pressed portions are provided to the both side surfaces sandwiching the central axis of the cut off wire at axially same locations; the opening size of the pressed portions provided to the both sides sandwiching the central axis of the cut off wire is constant and equal in the circumferential direction of the cut off wire; and at least one pair of concave pressed portions are provided in the axial direction of the cut off wire.

The board terminal according to the present aspect is used as a terminal connecting boards that mutually connects two printed boards, when the longitudinal both end portions are respectively soldered to the two printed boards. According to the present aspect, the pair of concave pressed portions are provided to the opposing both side surfaces at the axially same locations of the cut off wire. Thus, a cross-sectional area of the cut off wire is small in a portion sandwiched by the pair of concave pressed portions. Accordingly, the rigidity is partially reduced, and thus a stress reduction effect can be achieved. Since the pair of pressed portions are provided at the axially same locations in particular, axial extension can be stably achieved, and an axial stress reduction effect can further be stably achieved. Consequently, in a case where the board terminal of the present aspect is soldered between two printed boards stacked having an insulation board in between, for instance, a portion to which the pair of concave pressed portions are provided and deemed vulnerable are extended, even when the insulation board is expanded due to heat of soldering and the both printed boards are mutually separated. Thus, the axial stress exerted on the board terminal can be reduced, and thereby a solder crack can be prevented. In addition, when a plurality of pairs of pressed portions are provided, a more excellent stress reduction effect can be obtained.

Another aspect of the present invention provides a board terminal including a metal wire, and concave portions formed on peripheral surfaces along the length of the wire. The metal wire may be cut to a predetermined length, and the concave portions may be formed by pressing the peripheral surfaces of the wire at intermediate portions along the length thereof. The concave pressed portions may be formed in opposite peripheral surfaces of the wire at locations offset in the axial direction. The concave pressed portions formed in the opposite peripheral surfaces of the wire may partially overlap in the axial direction.

The opening size of each concave pressed portion may increase along a lateral direction of the wire from a first side to a second side. The concave pressed portions may be formed in opposite peripheral surfaces of the wire, and the opening sizes of the concave pressed portions on the opposite peripheral surfaces of the wire may increase in opposite lateral directions. The depth of each concave pressed portion may increase along a lateral direction of the wire from a first side to a second side. The concave pressed portions may be formed in opposite peripheral surfaces of the wire, and the depths of the concave pressed portions on the opposite peripheral surfaces of the wire may increase in opposite lateral directions.

The opening size of each concave pressed portion may be uniform along a lateral direction of the wire from a first side to a second side. The concave pressed portions may be formed in opposite peripheral surfaces of the wire at the same location in the axial direction to form a pair of concave pressed portions. At least two pairs of concave pressed portions may be provided at different locations in the axial direction. Both longitudinal end portions of the wire may be inserted in through-holes of two printed boards and soldered thereto, such that the pairs of concave pressed portions are located between the two printed boards.

A longitudinal end portion of the wire may be inserted in a through-hole of a printed board and soldered thereto. The wire may be inserted through a through-hole of a connector base, such that the concave pressed portions are located between the connector base and the printed board.

The present invention provides the concave pressed portions to the external peripheral surfaces of the cut off wire. Since the pressed portions are elastically deformed, the stress to the soldered portion can be reduced, and thus a solder crack can be prevented from occurring. In addition, an external projection in the perpendicular direction to the axis can be prevented, and thus excellent storage efficiency and handling can be achieved.

### BRIEF DESCRIPTION OF THE DRAWINGS

The present invention is further described in the detailed description which follows, with reference to the noted plurality of drawings by way of non-limiting examples of exemplary embodiments of the present invention, in which like reference numerals represent similar parts throughout the several views of the drawings, and wherein:

FIG. 1 is a side view of a board terminal according to a first embodiment of the present invention;

FIG. 2 is a side view of the board terminal shown in FIG. 1, from a view different from the view of FIG. 1;

FIG. 3 illustrates a manufacturing method of the board terminal shown in FIG. 1;

FIG. 4 illustrates a state in which the board terminal shown in FIG. 1 is mounted to a printed board;

FIG. 5 is a side view of a board terminal according to a second embodiment of the present invention;

FIG. 6 is a side view of the board terminal shown in FIG. 5, from a view different from the view of FIG. 5;

FIG. 7 is a side view of a board terminal according to a third embodiment of the present invention;

FIG. 8 is a side view of the board terminal shown in FIG. 7, from a view different from the view of FIG. 7; and

FIG. 9 illustrates a state in which the board terminal shown in FIG. 7 is mounted to a printed board.

### DETAILED DESCRIPTION OF PREFERRED EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

The embodiments of the present invention are explained below with reference to the drawings.

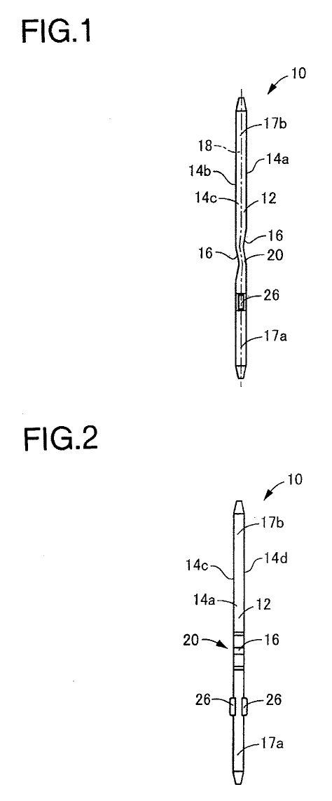

Firstly, a board terminal 10 according to a first embodiment of the present invention is shown in FIGS. 1 and 2. The board terminal 10 is formed of a wire 12 obtained by cutting a metal wire at a predetermined length, or a length of wire formed in any other suitable manner. The cut off wire 12 is formed of a conductive metal material, such as gold, copper, copper alloy, or any other suitable metal material; or another metal material, such as iron, having a surface coated with the conductive metal material. The cut off wire 12 may have any suitable shape, such as a substantially square cross-sectional shape having a small diameter, and extends in a longitudinal direction (a vertical direction in FIGS. 1 and 2).

In the cut off wire 12, a pair of external peripheral surfaces 14a and 14b, opposite each other and having a central axis there between, are provided with concave pressed portions 16. The pressed portions 16 may have any suitable shape, such as a substantially V shape concaved inward in a perpendicular direction to the axis of the cut off wire 12. As shown in FIG. 2, the pressed portions 16 have a predetermined opening size along an entire width direction (a horizontal direction in FIG. 2) of the external peripheral surfaces 14a and 14b. The pressed portions 16 are provided to the external peripheral surfaces 14a and 14b, between both end portions 17a and 17b of the cut off wire 12, and may be slightly closer to the first end portion 17a from an axially central portion. Further, the pair of pressed portions 16 are provided to locations mutually offset in the axial direction of the cut off wire 12, and partially overlapping each other when viewed in the perpendicular direction to the axis of the cut off wire 12. The pair of pressed portions 16 provide a curved portion 20 to an axially intermediate portion of the cut off wire 12, the curved portion 20 being curved in a wave shape along a central axis line 18 connecting the cross-sectional center.

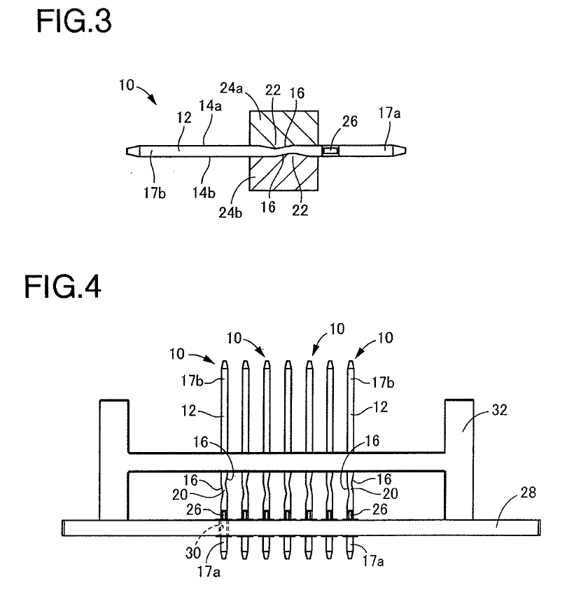

The pressed portions 16 are formed in any suitable manner, such as by sandwiching the cut off wire 12 using tools 24a and 24b having projections 22 corresponding to shapes of the pressed portions 16, and pressing both sides of the cut off wire 12 in the perpendicular direction to the axis, as shown in FIG. 3.

Flanges 26 may be formed slightly toward the end portion 17a from the pressed portions 16 on the external peripheral surfaces 14c and 14d to which no pressed portions 16 are provided. The flanges 26 are integrally provided to the cut off wire 12, projecting externally in the perpendicular direction to the axis of the cut off wire 12. The flanges 26 are formed in any suitable manner, such as by pressing the cut off wire 12.

The first end portion 17a of the board terminal 10 having the structure above is inserted through a through-hole 30 of a printed board 28 and soldered thereto, as shown in FIG. 4, for instance. Thereby, the board terminal 10 is provided projecting on the printed board 28. When the board terminal 10 is inserted through the through-hole 30, the flanges 26 are stopped or locked by the printed board 28, ensuring that the board terminal 10 is provided at a constant height. In FIG. 4, the board terminal 10 is inserted through a connector base 32, as well as through the through-hole 30. The curved portion 20 is positioned between the printed board 28 and the connector base 32. However, the connector base 32 is not necessarily required. The board terminal 10 may also be provided as projecting only from the printed board 28.

The board terminal 10 having the structure according to the present embodiment is provided with the concave pressed portions 16, which are easily elastically deformed. Due to the elastic deformation of the pressed portions 16, it is possible to reduce occurrence of solder cracks. In the present embodiment in particular, the pair of pressed portions 16 are provided to the opposing offset locations on the external peripheral surfaces 14a and 14b, and thus the curved portion 20 has a wave shape. Thereby, a more excellent stress dispersion effect can be achieved.

Further, the board terminal 10 of the present embodiment is formed of the cut off wire 12 having an appropriate thickness in a pressed direction of the pressed portions 16. Thus, the pressed portions 16 are provided having no lateral projection in the direction perpendicular to the axis. Accordingly, the transportation problems associated with a cranked structure, which is conventionally employed to prevent solder cracks, including reel winding and the like, can be solved. Separate processing on a manufacturing line, such as for forming a step-shaped bent portion, can also be eliminated. Furthermore, since the board terminal 10 has no cranked portion, the board terminal 10 can be handled similar to a conventional linear or flat terminal when being assembled to the printed board 28. Thus, a facility similar to that for the conventional linear terminal can be used. In addition, since the cut off wire 12 is obtained by cutting the metal wire, hardly any waste material is generated, and the board terminal 10 can be manufactured at a high yield.

In addition, the pressed portions 16 are provided without projecting externally in the perpendicular direction to the axis of the cut off wire 12. Thus, a plurality of board terminals 10 can be bundled effectively in view of space, and the storage efficiency and transportation efficiency can be enhanced.

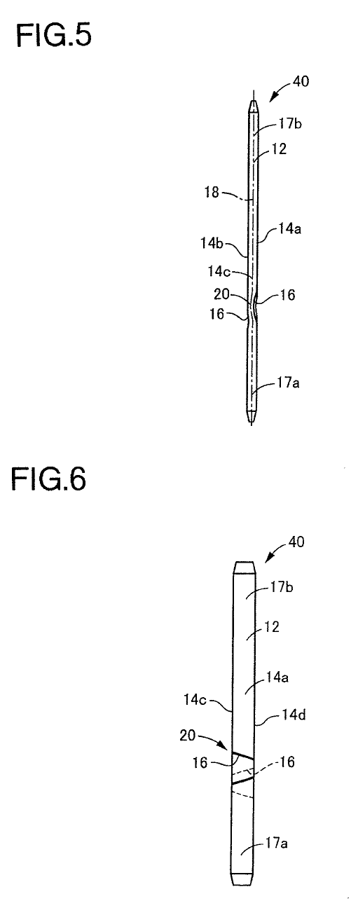

A board terminal 40 is shown next in FIGS. 5 and 6, as a second embodiment of the present invention. In the explanations below, materials and portions substantially similar to those in the first embodiment are provided in the drawing with the same reference numerals as those in the first embodiment, and explanations thereof are appropriately omitted.

The cut off wire 12 of the board terminal 40 may have any suitable shape, such as a cross-sectionally rectangular flat shape. The pressed portions 16 are provided to the pair of opposing external peripheral surfaces 14a and 14b sandwiching a central axis of the cut off wire 12. The pressed portions 16 are provided to locations mutually offset in an axial direction of the cut off wire 12, and partially overlapping each other when viewed in a perpendicular direction to the axis of the cut off wire 12. Further, an opening size of the pair of pressed portions 16 of the present embodiment is gradually widened from a first side toward a second side in a circumferential or width direction (a horizontal direction of FIG. 6) of the cut off wire 12. The opening size may be gradually widened from the first side toward the second side uniformly in the same circumferential direction. Further, both the size and depth of the opening may be increased.

The board terminal 40 of the present embodiment is not provided with the flanges 26, which are provided to the board terminal 10 of the first embodiment. The flanges 26 are not necessarily required in the prevent invention, but may be provided.

According to the present embodiment, the opening size of the pressed portions 16 changes in the circumferential direction of the cut off wire 12. Thereby, a more effective diffusion effect can be obtained for a stress in a twisted direction around the central axis line 18. In particular, the pair of pressed portions 16 on the opposite side surfaces may be widened in opposite directions perpendicular to the axis of the cut off wire 12. Thus, the curved portion 20 formed by the pressed portions 16 can be more easily elastically deformed, and a more excellent stress dispersion effect can be achieved.

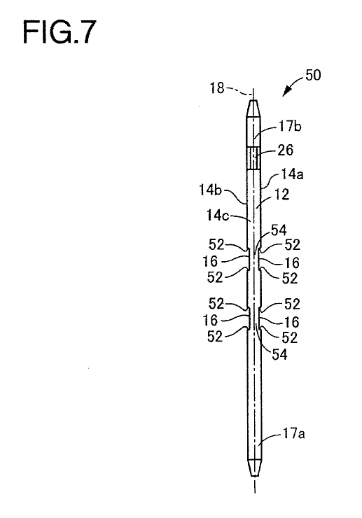

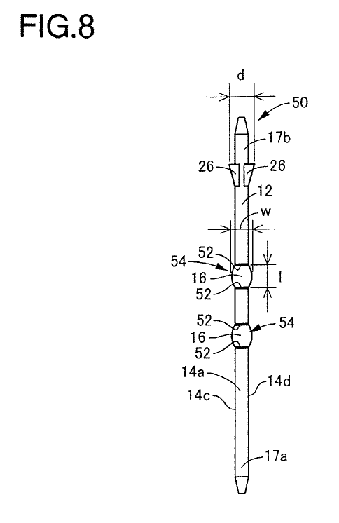

A board terminal 50 is shown next in FIGS. 7 and 8, as a third embodiment of the present invention. In the explanations below, materials and portions substantially similar to those in the first embodiment are provided in the drawing with the same reference numerals as those in the first embodiment, and explanations thereof are appropriately omitted. The cut off wire 12 of the board terminal 50 may have any suitable shape, such as a substantially square cross-sectional shape loosely insertable to a through-hole 30 described hereinafter, and linearly extends in the axial direction (vertical direction in FIGS. 7 and 8). The pair of pressed portions 16 are provided to an axially intermediate portion between the both end portions 17a and 17b on the pair of opposing external peripheral surfaces 14a and 14b sandwiching the central axis line 18 of the cut off wire 12. In the present embodiment, two pairs of the pressed portions 16 are provided having an appropriate distance in between in the axial direction of the cut off wire 12. Each pair of the pressed portions 16 includes the pressed portion 16 on the external peripheral surface 14a and the pressed portion 16 of the external peripheral surface 14b.

The pressed portions 16 have a same stepped concave shape, recessed inward in the perpendicular direction to the axis of the cut off wire 12. Both axial end portions of the pressed portion 16 of the cut off wire 12 are stepped surfaces 52 substantially perpendicular to the external surface 14a (14b). Further, the pressed portion 16 has a predetermined opening size in the circumferential direction of the cut off wire 12, and is provided in an entire width direction (horizontal direction in FIG. 8) of the external peripheral surface 14a (14b).

The pair of pressed portions 16 are provided to the external peripheral surfaces 14a and 14b at the axially same locations of the cut off wire 12. Thus, a stress reducing portion 54 having a small cross-sectional area is provided to the cut off wire 12 in a portion to which the pair of pressed portions 16 are provided. Since the two pairs of pressed portions 16 are provided having an appropriate distance in between in the axial direction of the cut off wire 12, two stress reducing portions 54 are provided to the cut off wire 12.

In each of the stress reducing portions 54, the pair of pressed portions 16 are formed preferably by sandwiching the cut off wire 12 using tools having projections corresponding to shapes of the pressed portions 16, and pressing both sides of the cut off wire 12 in the perpendicular direction to the axis, similar to the first embodiment. As shown in FIG. 8, since the thickness of the cut off wire 12 sandwiched by the tools is transferred to a portion between the tools, the stress reducing portion 54 of the present embodiment slightly bulges laterally from the external peripheral surfaces 14a and 14b. A width w, which is widest in an axially middle portion of the cut off wire 12, is set within a range loosely insertable into through-holes 30 of printed boards 56a and 56b hereinafter described. In the present embodiment in particular, the maximum width w of the stress reducing portion 54 is provided substantially equal to an axial length 1 of the stress reducing portion 54 of the cut off wire 12. It is also possible to provide the stress reducing portion 54 so as not to bulge laterally from the external peripheral surfaces 14c and 14d, by pressing the external peripheral surfaces 14c and 14d with the tools.

Further, flanges 26 may be formed on the one end portion 17b of the cut off wire 12. The flanges 26 have a substantially triangle shape gradually projecting laterally in the perpendicular direction to the axis of the cut off wire 12 from the external peripheral surfaces 14c and 14d, toward the end portion 17b side. A distance d between ends of the flanges 26 on the end portion 17b side is provided greater than an internal diameter of the through-holes 30 of the printed boards 56a and 56b hereinafter described. The flanges 26 may be formed by partially pressing the cut off wire 12.

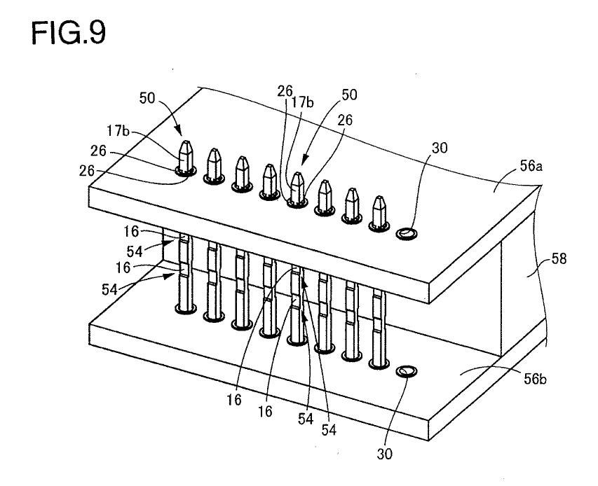

The board terminal 50 having the structure above is suitably used as a terminal connecting board that connects the pair of printed boards 56a and 56b, as shown in FIG. 9. The printed boards 56a and 56b are stacked sandwiching an insulation board 58 formed of any suitable material, such as nonconductive synthetic resin. The plurality of through-holes 30 are provided penetrating a lateral peripheral end portion projecting from the insulation board 58 and having a predetermined distance in between.

Then, the end portion 17a of the board terminal 50, to which the flanges 26 are not provided, is inserted through the through-holes 30 of the pair of printed boards 56a and 56b externally from a stacking direction of the printed boards 56a and 56b. The board terminal 50 is loosely insertable through the through-holes 30 of the printed boards 56a and 56b. The flanges 26 are locked at an opening peripheral end portion of the through-hole 30 of the printed board 56a, and thereby an insertion amount is regulated. The end portion 17a is inserted through the through-hole 30 of the printed board 56b and soldered thereto; and the end portion 17b is inserted through the through-hole 30 of the printed board 56a and soldered thereto. The board terminal 50 is thus electrically connected to both printed boards 56a and 56b, which are then electrically connected via the board terminal 50.

The board terminal 50 is provided with the stress reducing portions 54 in the axially intermediate portion. The stress reducing portions 54 are deemed partially vulnerable in the axial direction. Thus, even when the insulation board 58 is thermally expanded due to the heat of soldering and both printed boards 56a and 56b are separated, the stress reduction portions 54 of the cut off wire 12 are axially extended and deformed, and thus a stress is reduced. Thereby, cracks can be prevented from occurring in the soldered portions of the board terminal 50. Accordingly, electric connection of the both printed boards 56a and 56b can be further stably maintained. In particular, the pair of pressed portions 16 are provided in each of the stress reducing portions 54 on the opposite side surfaces at the axially same locations of the board terminal 50. Thus, axial extension in the stress reducing portions 54 are achieved in a well-balanced and further stable manner on both sides of the central axis line 18, and thereby a more effective reduction effect is achieved against an axial stress. In addition, both end portions of the pressed portions 16 are the stepped surfaces 52 expanding in the substantially perpendicular direction to the axis of the cut off wire 12. Thus, the difference in rigidity is further clear between portions provided with the stress reducing portions 54 and portions not provided therewith in the axial direction of the cut off wire 12. Axial deformation of the cut off wire 12 is more easily achieved in the stress reducing portions 54, which have a relatively low rigidity.

Further, the board terminal 50 is loosely inserted through the through-holes 30 of the both printed boards 56a and 56b, thus reducing a possibility of damaging the through-holes 30. Concurrently, the board terminal 50 can be inserted externally from the stacking direction of the both printed boards 56a and 56b through the through-holes 30 of the printed boards 56a and 56b, and then can be soldered to the printed boards 56a and 56b. Thereby, a situation can be prevented in which insertion of board terminals through through-holes of the other printed board might adversely be affected due to alignment accuracy. Such a situation may occur, for example, when first end portions of board terminals are soldered and fixed to one printed board, and then second end portions of the plurality of board terminals fixed to the printed board are inserted through respective through-holes of the other printed board. Thus, the both printed boards 56a and 56b can be assembled with the board terminal 50 in a further stable and efficient manner.

Although not shown in a drawing, board terminals 50 may suitably be provided as a terminal connecting body in which a plurality of the board terminals are connected in parallel to a connecting material formed of a suitable material, such as a metal plate. Winding the connecting material can thus compactly store the plurality of board terminals. Further, matching an alignment pitch of the board terminals of the connecting material with an alignment pitch of the through-holes of the printed boards, allows the connecting material to be cut in a predetermined number so as to provide a plurality of board terminals. Then, the plurality of board terminals can be inserted at one time through the through-holes of the printed boards, while the connection to the connecting material is maintained.

The embodiments of the present invention are explained above in detail. However, the present invention is not limited by specifics of the explanations. For example, the board terminals 10 and 40 of the first and second embodiments, respectively, may have the pressed portion 16 on only one of the external peripheral surfaces 14a and 14b. Further, the board terminal 40 of the second embodiment may have the pair of pressed portions 16 having the opening size gradually widened in the same circumferential direction of the cut off wire 12. The pair of pressed portions 16 may have the opening size widened in opposing directions, or one of the pressed portions 16 may have a constant opening size as in the first embodiment.

In the third embodiment, the pair of pressed portions 16 may be provided in any numbers. Only one pair of pressed portions 16 may be provided in the axial direction of the cut off wire 12. Alternatively, three or more pairs may be provided. Further, the pressed portions 16 of the pair of stress reducing portions 54 are provided on the same external peripheral surface 14a or 14b in the embodiment. The pressed portions 16 of one of the stress reducing portions 54 may instead be provided to external peripheral surfaces 14c and 14d, which are different from the other stress reducing portion 54, for instance. Furthermore, the pressed portions 16 may be provided to mutually same locations in the axial directions on all four external peripheral surfaces 14a, 14b, 14c, and 14d. Then, when the cut off wire 12 is pressed along an entire periphery in the perpendicular direction to the axis, the stress reducing portion concaved along the entire periphery may be provided.

In addition, the flanges 26 are not necessarily required in the third embodiment. For example, an insertion amount to the through-holes of the printed board may be regulated by positioning and supporting the board terminal with a soldering tool, without providing the flanges 26.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed:

1. A board terminal comprising:
a metal wire; and
concave portions formed on peripheral surfaces along the length of the wire.

2. The board terminal according to claim 1, wherein the metal wire is cut to a predetermined length, and the concave portions are formed by pressing the peripheral surfaces of the wire at intermediate portions along the length thereof.

3. The board terminal according to claim 2, wherein the concave pressed portions are formed in opposite peripheral surfaces of the wire at locations offset in the axial direction.

4. The board terminal according to claim 3, wherein the concave pressed portions formed in the opposite peripheral surfaces of the wire partially overlap in the axial direction.

5. The board terminal according to claim 2, wherein an opening size of each concave pressed portion increases along a lateral direction of the wire from a first side to a second side.

6. The board terminal according to claim 5, wherein the concave pressed portions are formed in opposite peripheral surfaces of the wire, and the opening sizes of the concave pressed portions on the opposite peripheral surfaces of the wire increase in opposite lateral directions.

7. The board terminal according to claim 2, wherein a depth of each concave pressed portion increases along a lateral direction of the wire from a first side to a second side.

8. The board terminal according to claim 7, wherein the concave pressed portions are formed in opposite peripheral surfaces of the wire, and the depths of the concave pressed portions on the opposite peripheral surfaces of the wire increase in opposite lateral directions.

9. The board terminal according to claim 2, wherein an opening size of each concave pressed portion is uniform along a lateral direction of the wire from a first side to a second side.

10. The board terminal according to claim 2, wherein the concave pressed portions are formed in opposite peripheral surfaces of the wire at the same location in the axial direction to form a pair of concave pressed portions.

11. The board terminal according to claim 10, wherein at least two pairs of concave pressed portions are provided at different locations in the axial direction.

12. The board terminal according to claim 11, wherein both longitudinal end portions of the wire are inserted in through-holes of two printed boards and soldered thereto, such that the pairs of concave pressed portions are located between the two printed boards.

13. The board terminal according to claim 12, wherein an opening size of each concave pressed portion is uniform along a lateral direction of the wire from a first side to a second side.

14. The board terminal according to claim 10, wherein an opening size of each concave pressed portion is uniform along a lateral direction of the wire from a first side to a second side.

15. The board terminal according to claim 2, wherein a longitudinal end portion of the wire is inserted in a through-hole of a printed board and soldered thereto.

16. The board terminal according to claim 15, wherein the wire is inserted through a through-hole of a connector base, such that the concave pressed portions are located between the connector base and the printed board.
